(19) United States
(12) Patent Application Publication
(10) Pub. No.: US 2006/0118049 A1
(43) Pub. Date: Jun. 8, 2006

(54) Vacuum-generating apparatus and thin film processing apparatus having the same

(76) Inventors: In-Ho Song, Cheonan-si (KR); Kwan-Young Cho, Cheonan-si (KR)

Correspondence Address: CANTOR COLBURN, LLP, 55 GRIFFIN ROAD SOUTH, BLOOMFIELD, CT, 06002, US

(21) Appl. No.: 11/261,961

(22) Filed: Oct. 28, 2005

(30) Foreign Application Priority Data
Dec. 6, 2004 (KR) 2004-101951

(51) Int. Cl. H01L 21/306; C23C 16/00

(52) U.S. Cl. 118/733; 118/715; 156/345.29

(57) ABSTRACT

A vacuum-generating apparatus includes a vacuum-generating unit and a stabilizing module. The vacuum-generating unit exhausts a fluid from a processing area to generate a vacuum pressure in the processing area. The stabilizing module is disposed between the processing area and the vacuum-generating unit, and the stabilizing module includes at least two curved fluid paths through which the fluid passes. The fluid is exhausted from the processing area through the curved fluid paths, to thereby improve uniformity of the vacuum pressure in the processing area.

### CROSS REFERENCE TO RELATED APPLICATION

This application claims priority to Korean Patent Application No. 2004-101951 filed on Dec. 6, 2004 and all the benefits accruing therefrom under 35 U.S.C. § 119, the contents of which are incorporated herein by reference in its entirety.

### BACKGROUND OF THE INVENTION

1. Field of the Invention

The present invention relates to a vacuum-generating apparatus and a thin film processing apparatus having the vacuum-generating apparatus. More particularly, the present invention relates to a vacuum-generating apparatus capable of improving uniformity of vacuum pressure in a processing area and a thin film processing apparatus having the vacuum-generating apparatus.

2. Description of the Related Art

In general, information-processing devices include a desktop computer, a notebook computer, a cellular phone, personal digital assistants (PDA), etc.

The majority of information-processing devices include a semiconductor chip for processing information and a display device for converting the information into images. Recently, liquid crystal display devices including a liquid crystal display panel having thin thickness and lightweight have been widely used.

The liquid crystal display device having the liquid crystal display panel includes films having a thin thickness. Examples of the thin films include a gate line, a data line, a semiconductor layer, a pixel electrode, a common electrode, an insulation layer, etc. The thin film is formed and patterned in a vacuum chamber.

Therefore, processing the thin films or thin film patterns requires a vacuum chamber and a vacuum-generating device that exhausts a gas from the chamber to generate vacuum pressure therein.

A conventional vacuum-generating device is directly coupled to a gas outlet of the chamber for generating a vacuum pressure within the chamber by exhausting gas from the chamber.

However, when the vacuum-generating device is directly coupled to the chamber, a pressure proximate the gas outlet is lower than a pressure in the chamber so the vacuum pressure in the chamber is exceedingly non-uniform or lowered.

Therefore, the quality of the thin films formed in the chamber is also exceedingly deteriorated.

### SUMMARY OF THE INVENTION

The present invention obviates above problems and thus the present invention provides a vacuum-generating apparatus capable of improving uniformity of vacuum pressure in a processing area.

The present invention also provides a thin film processing apparatus including the above vacuum-generating apparatus.

In accordance with an aspect of the present invention, there is provided a vacuum-generating apparatus including a vacuum-generating unit and a stabilizing module.

The vacuum-generating unit exhausts a fluid from a processing area to generate a vacuum pressure in the processing area. The stabilizing module is disposed between the processing area and the vacuum-generating unit, and the stabilizing module includes at least two curved fluid paths through which a fluid passes to improve uniformity of vacuum pressure in the processing area. The stabilizing module includes at least two exhausting plates, and the exhausting ports are formed on the exhausting plates. The exhausting ports formed on the exhausting plates are interlaced, or do not face each other or do not align, with each other when viewed on a plane. The exhausting ports formed on the exhausting plate are arranged in substantially parallel straight lines or in substantially circular shape when viewed on a plane.

In accordance with another aspect of the present invention, there is provided a thin film processing apparatus including a chamber, a vacuum-generating unit and a stabilizing module.

The chamber provides a thin film processing area, and the chamber has an opening portion. The vacuum-generating unit is spatially communicated with the chamber through the opening portion, and the vacuum-generating unit exhausts a fluid from the chamber to generate a vacuum pressure in the chamber. The stabilizing module is disposed between the chamber and the vacuum-generating unit, and the stabilizing module includes at least two curved fluid paths through which the fluid passes to improve a uniformity of vacuum pressure in the chamber. The stabilizing module includes at least two exhausting plates, and the exhausting ports formed on the exhausting plates are interlaced with each other when viewed on a plane. The exhausting ports formed on the exhausting plate are arranged in substantially parallel straight lines or in substantially circular shape when viewed on a plane.

In accordance with the present invention, the stabilizing module is disposed between the chamber and the vacuum-generating unit, and the stabilizing module distorts the path of the fluid, to thereby reduce non-uniformity of vacuum pressure in the processing area.

The vacuum-generating unit exhausts the fluid from the processing area to generate a vacuum pressure in the processing area. For example, the vacuum-generating unit may exhaust gas from the processing area to generate vacuum pressure in order to form a thin film on a substrate within the processing area.

The stabilizing module is disposed between the processing area and the vacuum-generating unit to improve uniformity of vacuum pressure. The stabilizing module includes at least two curved fluid paths through which the fluid, for example, a gas including an inert gas, passes.

In accordance with the present invention, the gas in the processing area is dispersed and exhausted through the curved fluid paths, to thereby improve uniformity of vacuum pressure in the processing area.

### BRIEF DESCRIPTION OF THE DRAWINGS

The above and other advantages of the present invention will become more apparent by describing in detail exemplary embodiments thereof with reference to the accompanying drawings, in which:

FIG. 1 is a cross-sectional view schematically illustrating a vacuum-generating apparatus in accordance with an exemplary embodiment of the present invention;

FIG. 2 is a perspective view illustrating spaced exhausting plates of the vacuum-generating apparatus in FIG. 1;

FIG. 3 is an exploded perspective view illustrating spaced exhausting plates in accordance with another exemplary embodiment of the present invention;

FIG. 4 is an exploded perspective view illustrating spaced exhausting plates in accordance with another exemplary embodiment of the present invention;

FIG. 5 is a cross-sectional view schematically illustrating a vacuum-generating apparatus in accordance with another exemplary embodiment of the present invention;

FIG. 6 is a cross-sectional view schematically illustrating a vacuum-generating apparatus in accordance with another exemplary embodiment of the present invention; and

FIG. 7 is a cross-sectional view illustrating an apparatus for manufacturing a thin film in accordance with an exemplary embodiment of the present invention.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or substrate is referred to as being “on” or “onto” another element, it can be directly disposed on the other element or intervening elements may also be present.

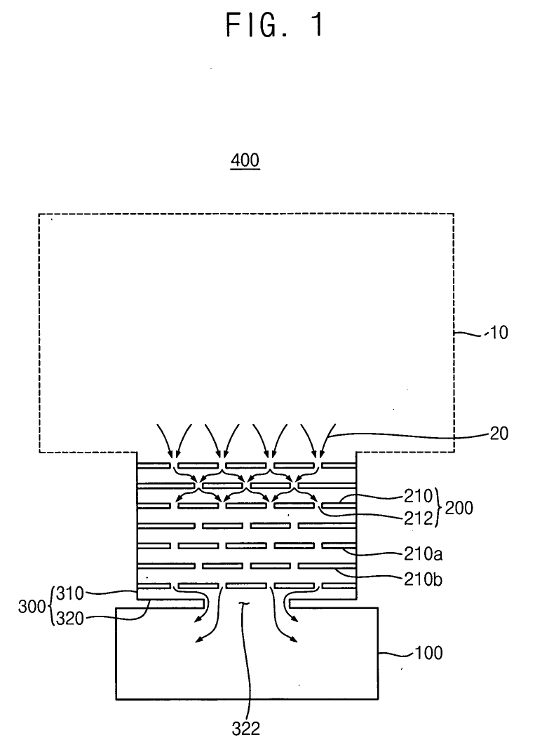

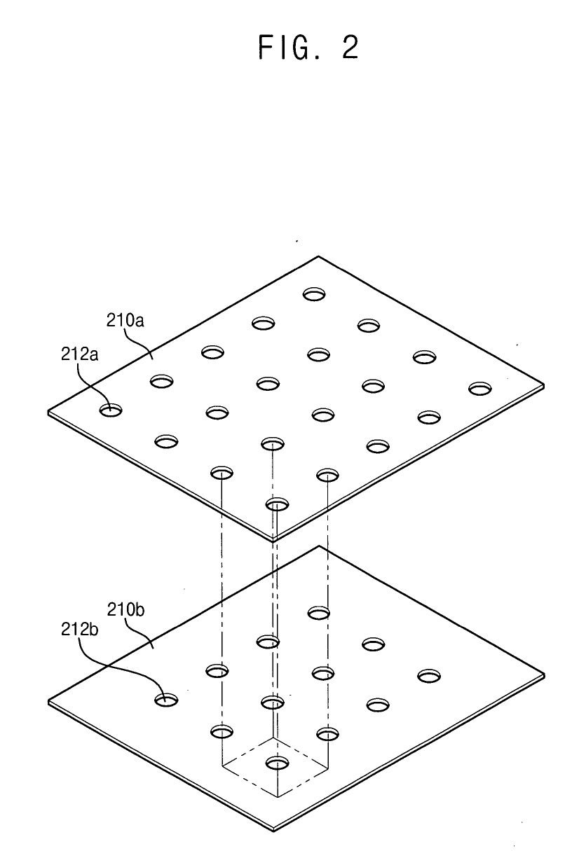

FIG. 1 is a cross-sectional view schematically illustrating a vacuum-generating apparatus in accordance with an exemplary embodiment of the present invention. FIG. 2 is a perspective view illustrating spaced exhausting plates of the vacuum-generating apparatus in FIG. 1.

Referring to FIGS. 1 and 2, a vacuum-generating apparatus 400 includes a vacuum-generating unit 100 and a stabilizing module 200.

The vacuum-generating unit 100 is configured to generate a vacuum pressure in a processing area 10 by exhausting a fluid 20, for example but not limited to a gas, from the processing area 10.

The vacuum-generating unit 100 in accordance with the present embodiment includes a motor that induces a vacuum pump to exhaust the fluid from the processing area 10. Alternatively, any apparatus or combination thereof capable of exhausting the fluid from the processing area 10 may be used as the vacuum-generating unit 100.

The stabilizing module 200 is disposed between the processing area 10 and the vacuum-generating unit 100 to improve uniformity of the vacuum pressure within the processing area 10. The stabilizing module 200 may include at least two curved fluid paths through which the fluid, for example, gas, passes in a curved direction.

The stabilizing module 200 includes at least two exhausting plates 210 coupled to each other, such as but not limited to, laminated to each other.

Each of the exhausting plates 210 has a plurality of apertures or exhausting ports 212. The exhausting ports 212 are formed on each of the exhausting plates 210 such that the exhausting ports are interlaced with each other between adjacent ones of the exhausting plates. In other words, the exhausting ports 212 may not correspond to or not aligned with each other between adjacent exhausting plates 210 when viewed on a plane, as illustrated in FIGS. 1 and 2. That is, the exhausting ports 212 disposed through the exhausting plates 210 are interlaced with each other when viewed on a plane. The configuration of the exhausting ports 212 among the exhausting plates 210 urges the fluid to change directions as the fluid passes the plates from the processing area 10 through the stabilizing module 200. In this embodiment, the exhausting ports 212 have a substantially circular shape or a substantially oval shape. The respective exhausting ports 212 have a substantially same size. In other words, a cross-sectional area of each exhausting port is substantially constant among the exhausting ports. Alternative embodiments include configurations of apertures or exhausting ports 212 whose position and configuration vary as disposed on a single exhausting plate 210 or among the exhausting ports 212 disposed on the plurality of exhausting plates 210.

In the present embodiment, the exhausting plates 210 are defined as an N-th exhausting plate and an (N+1)-th exhausting plate and an (N+2)-th exhausting plate (N denotes a natural number).

The N-th exhausting plate 210a has an N-th exhausting port group including at least two exhausting ports 212a. The N-th exhausting ports 212a in the N-th exhausting port group are formed on the N-th exhausting plate to be arranged in substantially parallel straight lines, as illustrated in FIG. 2.

The (N+1)-th exhausting plate 210b has an (N+1)-th exhausting port group including at least two exhausting ports 212b. The (N+1)-th exhausting ports 212b in the (N+1)-th exhausting port group are formed on the (N+1)-th exhausting plate to be arranged in substantially parallel straight lines.

The exhausting ports 212a included in the N-th exhausting port group are formed on the N-th exhausting plate 210a so as not to correspond to or do not align with the exhausting ports 212b included in the (N+1)-th exhausting port group, as illustrated with phantom lines in FIG. 2.

The exhausting ports 212b included in the (N+1)-th exhausting port group are arranged between the exhausting ports 212a included in the N-th exhausting port group when viewed on a plane. In other words, the exhausting ports 212b included in the (N+1)-th exhausting port group are disposed inside the four exhausting ports 212a that are adjacent to each other when viewed on a plane.

Of course, alternative exemplary embodiments include configurations where the outer periphery of the exhausting plates 210 is not a square or rectangular shape as illustrated in FIGS. 1 and 2. For example the outer periphery may be a circular or an irregular shape depending on the intended design and function of the stabilizing module 200, or processing area 10.

The vacuum-generating apparatus 400 further includes a fixing member 300 connecting the exhausting plate 210 to the vacuum-generating unit 100.

The fixing member 300 includes a bottom part 320 and a sidewall 310 extended from an edge portion of the bottom part 320 to form a receiving space.

The exhausting plates 210 are fixed by the fixing member 300. The exhausting plates 210 are coupled to the sidewall 310 of the fixing member 300. An aperture or opening portion 322 is formed at the bottom part 320. The opening portion 322 is configured such that the vacuum-generating unit 100 is in fluid communication with the processing area 10 through the opening portion 322. Exemplary embodiments of the bottom part 320 of the fixing member 300 include configurations having a substantially plate shape. In this embodiment, the bottom part 320 extends in a direction substantially parallel to the exhausting plates 210.

In accordance with the present embodiment, a fluid 20 in the processing area 10 is exhausted from the processing area 10 through the curved paths formed by the exhausting ports 212 that are formed on the exhausting plates 210. The configuration of the exhausting ports 212 not in alignment between adjacent exhausting plates 210 results in a more uniform vacuum pressure distribution in the processing area 10. Therefore, the processing area 10 may maintain substantially uniform vacuum pressure therein.

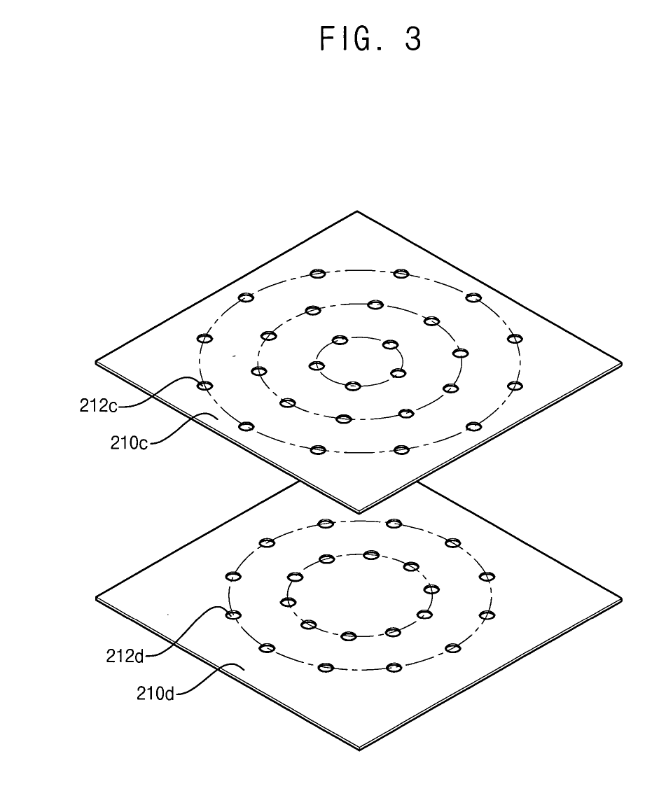

FIG. 3 is an exploded perspective view illustrating spaced exhausting plates in accordance with another exemplary embodiment of the present invention. In the present embodiment, only the configuration of the stabilizing module 200 differs from the previous embodiment. Therefore, only the details of an exemplary embodiment of the stabilizing module 200 will be discussed now. In FIG. 3, the same or similar reference numerals are used to refer to the same or like parts as those used previously.

Referring to FIGS. 1 and 3, a vacuum-generating apparatus 400 includes a vacuum-generating unit 100 and a stabilizing module 200.

The stabilizing module 200 is disposed between the processing area 10 and the vacuum-generating unit 100 to improve uniformity of vacuum pressure. The stabilizing module 200 includes at least two fluid paths through which the fluid 20, for example but not limited to, gas, passes in a curved direction.

In the present embodiment, the stabilizing module 200 may include at least two exhausting plates 210 coupled to each other, such as but not limited to, laminated to each other.

Each of the exhausting plates 210 has a plurality of apertures or exhausting ports 212. The exhausting ports 212 are formed on the exhausting plate 210 so that the exhausting ports 212 may not correspond to or do not aligned with each other between adjacent exhausting plates when viewed on a plane, as illustrated in FIGS. and 1 and 3. That is, the exhausting ports 212 disposed through the exhausting plates 210 are interlaced with each other when viewed on a plane. The configuration of the exhausting ports 212 among the exhausting plates 210 urges the fluid to change directions as the fluid passes between the plates from the processing area 10 through the stabilizing module 200. The exhausting port 212 may have a substantially circular shape or a substantially oval shape. Each of the exhausting ports 212 has substantially the same exhausting area. Alternative embodiments include configurations of apertures or exhausting ports 212 whose position and configuration vary as disposed on a single exhausting plate 210 or among the exhausting ports 212 disposed on the plurality of exhausting plates 210.

In the present embodiment, the exhausting plates 210 are defined as an N-th exhausting plate and an (N+1)-th exhausting plate and an (N+2)-th exhausting plate (N denotes a natural number).

The N-th exhausting plate 210c has an N-th exhausting port group including at least two apertures or exhausting ports 212c. The N-th exhausting ports 212c in the N-th exhausting port group are formed on the N-th exhausting plate 210c to be arranged in a substantially circular shape having a substantially same center, as illustrated in FIG. 3.

The (N+1)-th exhausting plate 210d has an (N+1)-th exhausting port group including at least two apertures or exhausting ports 212d. The (N+1)-th exhausting ports 212d in the (N+1)-th exhausting port group are formed on the (N+1)-th exhausting plate 212d to be arranged in a substantially circular shape having a substantially same center.

The exhausting ports 212c included in the N-th exhausting port group are formed on the N-th exhausting plate 210c such that they are interlaced with, or not correspond to or not align with, the exhausting ports 212d included in the (N+1)-th exhausting port group.

The exhausting ports 212d included (N+1)-th exhausting port group are arranged between the exhausting ports 212c included in the N-th exhausting port group when viewed on a plane. In other words, the exhausting ports 212d are arranged in a substantially circular shape having a substantially same center and a different radius with respect to a circular arrangement of the exhausting ports 212c when viewed on a plane.

A fluid 20 in the processing area 10 is exhausted from the processing area 10 through the curved path formed by the exhausting ports 212 that are interlaced with each other. Therefore, this embodiment results in a more uniform vacuum pressure distribution in the processing area 10.

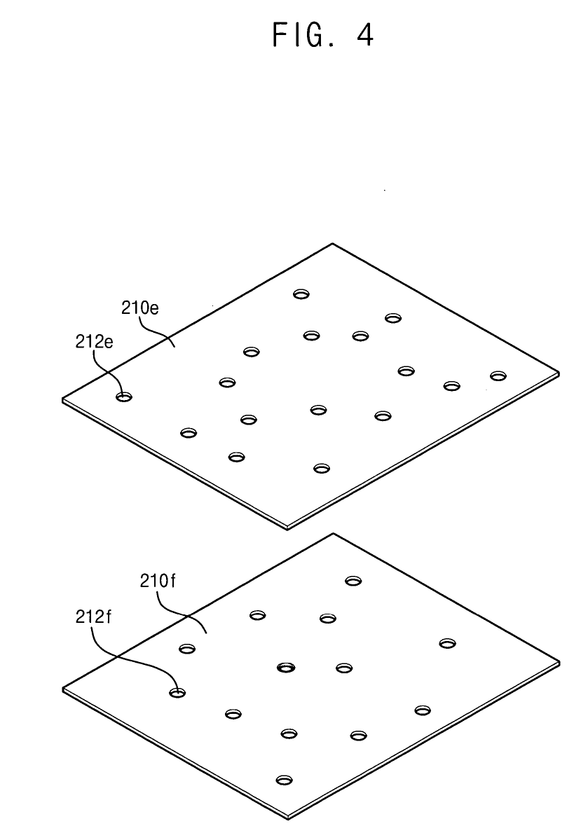

FIG. 4 is an exploded perspective view illustrating spaced exhausting plates 210 in accordance with another exemplary embodiment of the present invention. In the present embodiment, only the configuration of the stabilizing module 200 differs from the previous embodiments. Therefore, only the details of exemplary an embodiment of the stabilizing module 200 will be discussed now. In the present embodiment, the same or similar reference numerals are used to refer to the same or like parts as those used previously.

Referring to FIGS. 1 and 4, a vacuum-generating apparatus 400 includes a vacuum-generating unit 100 and a stabilizing module 200.

The stabilizing module 200 is disposed between the processing area 10 and the vacuum-generating unit 100 to improve uniformity of the vacuum. The stabilizing module 200 includes at least two fluid paths through which the fluid 20, for example but not limited to, a gas, passes in a curved direction.

In the present embodiment, the stabilizing module 200 includes at least two exhausting plates 210 coupled to each other, such as but not limited to, laminated to each other.

The exhausting plate 210 has a plurality of apertures or exhausting ports 212. The exhausting ports 212 are formed on the exhausting plates 210 such that the exhausting ports 212 are interlaced with, or do not face each other or do not align with, each other between adjacent plates 210 when viewed on a plane. Each of the exhausting ports 212 has a substantially circular shape or a substantially oval shape when viewed on a plane. Each of the exhausting ports 212 has substantially the same constant exhausting area. Alternative embodiments include configurations of apertures or exhausting ports 212 whose position and configuration vary as disposed on a single exhausting plate 210 or among the exhausting ports 212 disposed on the plurality of exhausting plates 210.

In the present embodiment, the exhausting plates 210 are defined as an N-th exhausting plate and an (N+1)-th exhausting plate and an (N+2)-th exhausting plate (N denotes a natural number).

The N-th exhausting plate 210e has an N-th exhausting port group including at least two apertures or exhausting ports 212e. The N-th exhausting ports 212e in the N-th exhausting port group are formed on the N-th exhausting plate 210e to be arranged at random.

The (N+1)-th exhausting plate 212f has an (N+1)-th exhausting port group including at least two exhausting ports 212f. The (N+1)-th exhausting ports 212f in the (N+1)-th exhausting port group are formed on the (N+1)-th exhausting plate 212f to be arranged at random.

The exhausting ports 212e included in the N-th exhausting port group are formed on the N-th exhausting plate 210e so as not to face or align with the exhausting ports 212f included in the (N+1)-th exhausting port group.

The fluid 20 in the processing area 10 is exhausted from the processing area 10 through the curved path formed by the exhausting ports 212 that are interlaced or do not align with each other. Therefore, this embodiment results in a more uniform vacuum pressure distribution in the processing area 10.

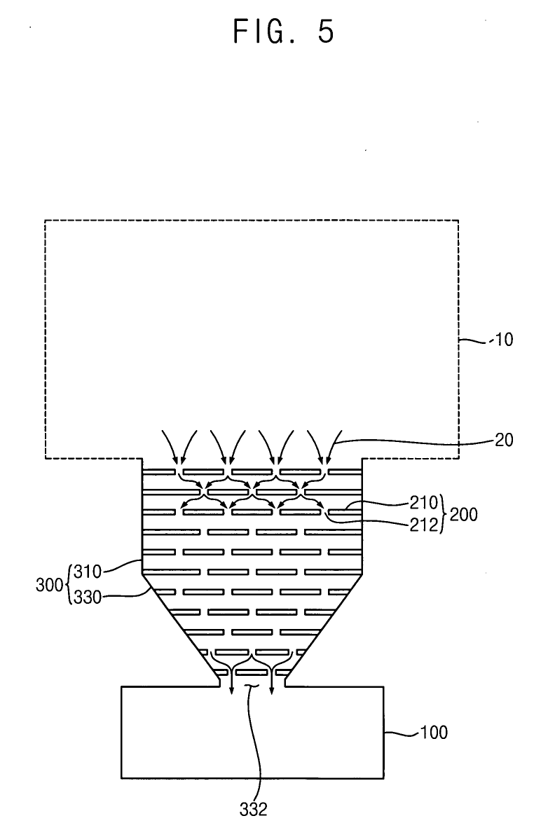

FIG. 5 is a cross-sectional view schematically illustrating a vacuum-generating apparatus in accordance with another exemplary embodiment of the present invention. In the present embodiment, a vacuum-generating apparatus has same function and structure as with previous embodiments except for the stabilizing module 200 and the fixing member 300. Therefore, only the different parts of the vacuum-generating apparatus will be described. In the present embodiment, the same or similar reference numerals are used to refer to the same or like parts as those previously used.

Referring to FIG. 5, a vacuum-generating apparatus 400 includes a vacuum-generating unit 100, a stabilizing module 200 and a fixing member 300.

The fixing member 300 includes a bottom part 330 and a sidewall 310 extended from an edge portion of the bottom part 330 to form a receiving space.

The fixing member 300 holds an exhausting plate 210. In other words, the exhausting plates 210 are coupled to the sidewall 310 of the fixing member 300. An opening portion 332, formed through the bottom part 330, is configured such that the vacuum-generating unit 100 is in fluid communication with the processing area 10 through an opening portion 322.

The bottom part 330 of the fixing member 300 has a substantially cone shape, in other words, the cross section of the bottom part 330 of the fixing member 300 becomes smaller the closer the cross section is to the bottom of the bottom part 330 or to the vacuum-generating unit 100.

The exhausting plates 210, disposed in the fixing member 300, having at least one exhausting port 212 direct an exhausting path of fluid 20. Alternatively, no exhausting plate may be disposed at the bottom part 330.

The fluid 20 in the processing area 10 may be effectively exhausted outside of the processing area 10 since the bottom part 330 of the fixing member 300 includes the substantially cone shape. Therefore, this embodiment results in a more uniform vacuum pressure distribution in the processing area 10.

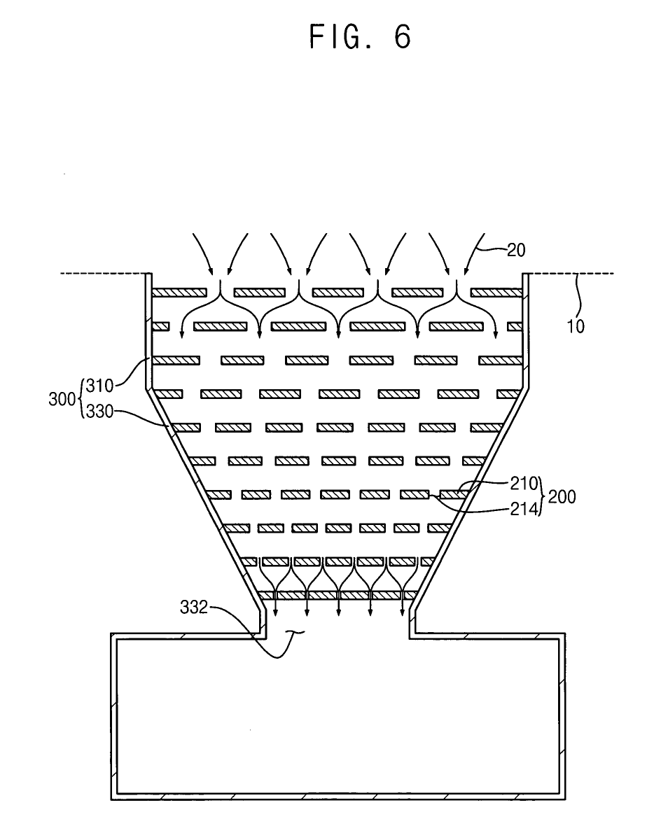

FIG. 6 is a cross-sectional view schematically illustrating a vacuum-generating apparatus in accordance with another exemplary embodiment of the present invention. In the present embodiment, a vacuum-generating apparatus has substantially same function and structure as in the previous embodiments except for the stabilizing module 200 and the fixing member 300. Therefore, only different parts to the vacuum-generating apparatus will be described in here. In the present embodiment, the same or similar reference numerals are used to refer to the same or like parts as those used previously.

Referring to FIG. 6, a vacuum-generating apparatus includes a vacuum-generating unit 100, a stabilizing module 200 and a fixing member 300.

The stabilizing module 200 is disposed between a processing area 10 and the vacuum-generating unit 100 to increase uniformity of vacuum pressure in the processing area 10. The stabilizing module 200 includes at least two fluid paths through which the fluid 20, for example, gas, passes in a curved direction.

The stabilizing module 200 includes at least two exhausting plates 210 coupled to each other, such as but not limited to, being laminated to each other.

The exhausting plate 210 has a plurality of apertures or exhausting ports 214. The exhausting ports 214 are formed on the exhausting plate 210 such that the exhausting ports 214 do not correspond to or do not align with each other between adjacent plates 210 when viewed on a plane. The exhausting port 214 has a substantially circular shape or a substantially oval shape when viewed on a plane. Each of the exhausting ports 214 has substantially the same size. Alternative embodiments include configurations of apertures or exhausting ports 214 whose position and configuration vary as disposed on a single exhausting plate 210 or among the exhausting ports 214 disposed on the plurality of exhausting plates 210

The fixing member 300 includes a bottom part 330 and a sidewall 310 extended from an edge portion of the bottom part 330 to form a receiving space.

The fixing member 300 holds the exhausting plates 210. In other words, the exhausting plates 210 are coupled to the sidewall 310 of the fixing member 300. An opening portion 332, formed at the bottom part 330, is configured such that the vacuum-generating unit 100 is in fluid communication with the vacuum-generating unit 100 through the opening portion 332.

The bottom part 330 of the fixing member 300 has a substantially cone shape, in other words, a cross-section of the bottom part 330 becomes smaller the closer the cross-section is to the bottom of the bottom part 330 or to the vacuum-generating unit 100. The exhausting plate 210 is disposed proximate the bottom part 330 and configured to direct the exhausting path of a fluid 20.

Each of the exhausting plates 210 includes a plurality of apertures or exhausting ports 214. A cross-section of an exhausting port 214 becomes larger the greater the distance is from the exhausting plate 210 on which the exhausting port 214 is formed to the opening portion 332 of the bottom part 330. Alternatively, the cross-section of the exhausting ports 214 may become smaller the greater the distance is from the exhausting plate 210 on which the exhausting port 214 is formed to the opening portion 332. Furthermore, the plurality of apertures or exhausting ports 214 are disposed on the exhausting plates 210 such that exhausting ports 214 do not align between adjacent plates 210, as illustrated in FIG. 6.

In one exemplary embodiment, for example, the cross-section of the exhausting port 214 adjacent to the bottom part 330 increases in proportion to the distance between the exhausting plate 210 and the opening portion 332. However, the cross-section of the exhausting port 214 adjacent to the sidewall 310 is preferably constant relative to the distance between the exhausting plate 210 and the opening portion 332.

Therefore, the fluid 20 in the processing area 10 may be effectively exhausted toward the vacuum generating unit 100 since the cross-section of the exhausting port 214 adjacent to the bottom part 330 increases in proportion to the distance between the exhausting plate 210 and the opening portion 332. Therefore, this embodiment results in a more uniform vacuum pressure distribution in the processing area 10.

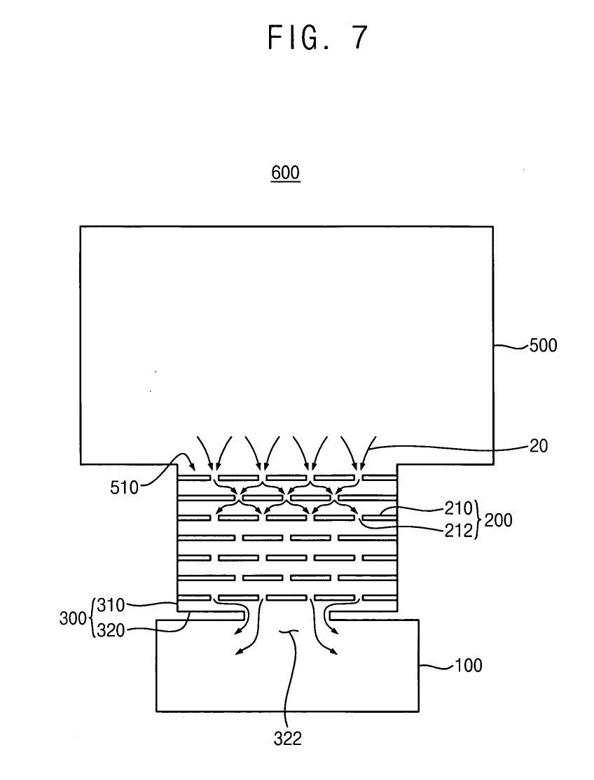

FIG. 7 is a cross-sectional view illustrating an apparatus for manufacturing a thin film in accordance with an exemplary embodiment of the present invention.

Referring to FIG. 7, a thin film processing apparatus 600 includes a chamber 500, a vacuum-generating unit 100 and a stabilizing module 200.

The chamber 500 provides a space in which a thin film process is performed. The thin film process includes depositing a metal layer or a non-metal layer onto a substrate (not shown).

The chamber 500 includes a first opening portion 510 exhausting a fluid 20, for example but not limited to, inert gas, outside of the chamber 500. A getter (not shown) that facilitates absorption of the fluid may be disposed in the chamber 500 to control the vacuum state in the chamber 500.

The vacuum-generating unit 100 is disposed to be spatially communicated with the chamber 500 through the first opening portion 510. The vacuum-generating unit 100 exhausts the fluid 20 to generate a vacuum state in the chamber 500.

The stabilizing module 200 is disposed between the chamber 500 and the vacuum-generating unit 100 to improve uniformity of a vacuum in the chamber 500. The stabilizing module 200 includes at least two fluid paths through which the fluid 20, for example, gas, passes in a curved direction.

The stabilizing module 200 includes at least two exhausting plates 210 coupled to each other, such as but not limited to, laminated to each other.

The exhausting ports 212 are formed on the exhausting plate 210 such that the exhausting ports 212 do not correspond to or do not align with each other between adjacent plates 212 when viewed on a plane. Each of the exhausting ports 212 has substantially the same circular shape or substantially the same oval shape when viewed on a plane. The respective exhausting ports 212 may have a substantially same size. Alternatively, a cross-section of the exhausting port 212 may increase or decrease as the distance changes between the exhausting port 212 and the vacuum-generating unit 100.

The exhausting ports 212 are arranged in lines on the exhausting plate 210. Alternatively, the exhausting ports 212 may be arranged in a substantially circular shape or at random.

The vacuum-generating apparatus 600 may further include a fixing member 300 connecting the exhausting plate 210 to the vacuum-generating unit 100.

The fixing member 300 includes a bottom part 320 and a sidewall 310 extended from an edge portion of the bottom part 320 to form a receiving space.

The fixing member 300 holds the exhausting plates 210. The exhausting plates 210 are coupled to the sidewall of the fixing member 300. An opening portion 322, formed at the bottom part 320, is configured such that the vacuum-generating unit 100 is in fluid communication with the processing area 10 through the opening portion 322.

The bottom part 320 of the fixing member 300 has a substantially plate shape. Alternatively, the bottom part 320 may has a cone shape, in other words, a cross-section of the bottom face becomes smaller as it gets closer to the opening portion 322 proximate the vacuum-generating unit 100.

The fluid 20 in the chamber 500 is dispersed and exhausted from the chamber 500 through the curved path formed by the exhausting ports 212 interlaced with each other. Therefore, this embodiment results in a more uniform vacuum pressure distribution in the chamber 500.

The fixing member 300 that holds the exhausting plates 210 may have a bottom part substantially cone shaped, in other words, the cross-section of the bottom part 320 becomes smaller as it gets closer to the vacuum-generating unit 100, thereby further effectively exhausting the fluid from the chamber 500 through the bottom part 320.

As described in the embodiments above, the exhausting ports 212 are configured and positioned on the exhausting plates 210, so that the fluid 20 in the processing area 10 or chamber 500 is dispersed and exhausted outside the processing area 10, while effectively achieving a more uniform vacuum pressure distribution in the processing area 10.

Having thus described exemplary embodiments of the present invention, it is to be understood that the invention defined by the appended claims is not to be limited by particular details set forth in the above description as many apparent variations thereof are possible without departing from the spirit or scope thereof as hereinafter claimed.

What is claimed is:

1. A vacuum-generating apparatus comprising:
a vacuum-generating unit that exhausts a fluid from a processing area to generate a vacuum pressure in the processing area; and
a stabilizing module disposed between the processing area and the vacuum-generating unit, the stabilizing module including at least two curved fluid paths through which the fluid passes so that the processing area maintains substantially uniform vacuum pressure therein.

2. The vacuum-generating apparatus of claim 1, wherein the stabilizing module comprises at least two exhausting plates each including exhausting ports, the exhausting ports being formed on the exhausting plates such that the exhausting ports are interlaced with each other between adjacent ones of the exhausting plates.

3. The vacuum-generating apparatus of claim 2, wherein the stabilizing module comprises an N-th (N is a natural number) exhausting plate, and the N-th exhausting plate comprises an N-th exhausting port group comprising at least two exhausting ports.

4. The vacuum-generating apparatus of claim 3, wherein the exhausting ports of the N-th exhausting port group are arranged in substantially parallel straight lines when viewed on a plane, wherein N denotes a natural number.

5. The vacuum-generating apparatus of claim 3, wherein the exhausting ports of the N-th exhausting port group are arranged in a substantially circular shape when viewed on a plane.

6. The vacuum-generating apparatus of claim 3, wherein the stabilizing module comprises an (N+1)-th exhausting plate, and the (N+1)-th exhausting plate comprises an (N+1)-th exhausting port group including at least two exhausting ports that are interlaced with the exhausting ports of the N-th exhausting port group.

7. The vacuum-generating apparatus of claim 6, wherein the exhausting ports of the (N+1)-th exhausting port group are arranged in substantially parallel straight lines when viewed on a plane.

8. The vacuum-generating apparatus of claim 6, wherein the exhausting ports of the (N+1)-th exhausting port group are arranged in a substantially circular shape when viewed on a plane.

9. The vacuum-generating apparatus of claim 2, wherein a cross-sectional area of each of the exhausting ports is substantially constant among the exhausting ports.

10. The vacuum-generating apparatus of claim 2, further comprising a fixing member being configured to hold the exhausting plates, the fixing member allowing the vacuum-generating unit to be in fluid communication with the processing area.

11. The vacuum-generating apparatus of claim 10, wherein the fixing member comprises a sidewall configured to hold the exhausting plates and a bottom part at which an opening portion is formed, and the fixing member is configured to allow fluid communication between the vacuum-generating unit and the processing area through the opening portion.

12. The vacuum-generating apparatus of claim 11, wherein the bottom part has a substantially plate shape extending in a direction substantially parallel to the exhausting plates.

13. The vacuum-generating apparatus of claim 11, wherein the bottom part has a substantially cone shape having a cross-section that becomes smaller as the cross-section gets closer to the vacuum-generating unit.

14. The vacuum-generating apparatus of claim 11, wherein a cross-section of an exhausting port becomes larger the further the exhausting port is spaced apart from the opening portion.

15. The vacuum-generating apparatus of claim 14, wherein the exhausting ports are arranged in a substantially circular shape.

16. The vacuum-generating apparatus of claim 11, wherein a cross-section of an exhausting port becomes smaller the further the exhausting port is spaced apart from the opening portion.

17. The vacuum-generating apparatus of claim 16, wherein the exhausting ports are arranged in a substantially circular shape.

18. The vacuum-generating apparatus of claim 2, wherein the exhausting ports formed on the exhausting plate are arranged at random when viewed on a plane.

19. A thin film processing apparatus comprising:
a chamber providing a thin film processing area, the chamber having an opening portion;
a vacuum-generating unit spatially communicated with the chamber through the opening portion, the vacuum-generating unit exhausting a fluid from the chamber to generate vacuum pressure in the chamber; and
a stabilizing module disposed between the chamber and the vacuum-generating unit, the stabilizing module comprising at least two curved fluid paths through which the fluid passes so that the chamber maintains substantially uniform vacuum pressure therein.

20. The thin film processing apparatus of claim 19, wherein the stabilizing module comprises at least two exhausting plates each including exhausting ports, the exhausting ports being formed on the exhausting plates such that the exhausting ports are interlaced with each other between adjacent ones of the exhausting plates.

21. The thin film processing apparatus of claim 20, wherein the stabilizing module comprises an N-th (N is a natural number) exhausting plate, and the N-th exhausting plate comprises an N-th exhausting port group comprising at least two exhausting ports.

22. The thin film processing apparatus of claim 21, wherein the exhausting ports of the N-th exhausting port group are arranged in substantially parallel straight lines when viewed on a plane.

23. The thin film processing apparatus of claim 21, wherein the exhausting ports of the N-th exhausting port group are arranged in a substantially circular shape when viewed on a plane.

24. The thin film processing apparatus of claim 21, wherein the stabilizing module comprises an (N+1)-th exhausting plate, and the (N+1)-th exhausting plate comprises an (N+1)-th exhausting port group comprising at least two exhausting ports.

25. The thin film processing apparatus of claim 24, Wherein the exhausting ports of the (N+1)-th port group are interlaced with the exhausting ports of the N-th exhausting port group, and the exhausting ports of the (N+1)-th exhausting port group are arranged in parallel straight lines when viewed on a plane.

26. The thin film processing apparatus of claim 20, further comprising a fixing member being configured to hold the exhausting plates, the fixing member being configured to allow the vacuum-generating unit to be in fluid communication with the chamber.

27. The thin film processing apparatus of claim 26, wherein the fixing member comprises a sidewall configured to hold the exhausting plates and a bottom part at which an opening portion is formed, the fixing member being configured to allow the vacuum-generating unit to be in fluid communication with the chamber through the opening portion.

28. The thin film processing apparatus of claim 27, wherein the bottom part has a substantially plate shape extending in a direction substantially parallel to the exhausting plates.

29. The thin film processing apparatus of claim 27, wherein the bottom part has a substantially cone shape having a cross-section that becomes smaller as the cross-section gets closer to the vacuum-generating unit.

30. The thin film processing apparatus of claim 27, wherein the exhausting ports are arranged in a substantially circular shape, and a cross-section of an exhausting port becomes larger the further the exhausting port is spaced apart from the opening portion.
